(19) United States
(12) Patent Application Publication
(10) Pub. No.: US 2018/0265961 A1
(43) Pub. Date: Sep. 20, 2018

(54) REACTIVE SPUTTERING APPARATUS AND REACTIVE SPUTTERING METHOD

(71) Applicant: CANON KABUSHIKI KAISHA, Tokyo (JP)

(72) Inventor: Tamayo Hiroki, Zama-shi (JP)

(21) Appl. No.: 15/916,108

(22) Filed: Mar. 8, 2018

(30) Foreign Application Priority Data
Mar. 14, 2017 (JP) 2017-047967

(51) Int. Cl. C23C 14/00

(52) U.S. Cl. CPC C23C 14/0042

(57) ABSTRACT

A reactive sputtering apparatus performs deposition in any of compound, transition, and metallic modes by employing a target and reactive gas, wherein the reactive sputtering apparatus includes an inert-gas feeding unit, a reactive-gas feeding unit, a power supply unit to supply electric power to the target, a detection unit to detect plasma emission generated upon supply of the electric power to the target, and a control unit to adjust a reactive-gas flow rate to maintain, at a designated value, plasma emission intensity at a wavelength or a value calculated from plasma emission intensities at plural wavelengths, and wherein the control unit controls the designated value for the plasma emission intensity or the calculated value thereof such that a ratio V/V_{c} of a cathode voltage V in the transition mode to V_{c} in the compound mode comes closer to a preset value, those voltages being detected during the deposition.

### BACKGROUND

### Field of the Disclosure

The present disclosure relates to a reactive sputtering apparatus and a reactive sputtering method.

### Description of the Related Art

A reactive sputtering process is known as a deposition method. In the reactive sputtering process, a compound film is formed on a deposition substrate by utilizing a sputtering phenomenon of a target material under a situation that reactive gas is introduced. In the case of forming an oxide film, for example, the oxide film is formed on the deposition substrate by generating discharge and causing sputtering of the target material under a situation that inert gas, such as Ar, and oxygen gas are introduced.

The reactive sputtering is divided into three modes in which deposition rates and film quality are different depending on the surface state of a target during film formation. Those modes are generally called a metallic mode, a transition mode, and a compound mode, and correspond to three different states. It is known that the three states in the reactive sputtering during the film formation can be explained using a physical model in consideration of inflow of the reactive gas, evacuation by a pump, and evacuation with the occurrence of reactions at the target surface (A. Pflug, Proceedings of the Annual Technical Conference. Society of Vacuum Coaters 2003, 241-247 (hereinafter referred to as “Non-Patent Literature 1”)).

In the compound mode, the reactive gas is present within a chamber in an amount sufficient to change an entire surface of the target in use from a metal into a compound, and a film of the compound is formed on the film formation substrate. In that state, the compound having a stoichiometric proportion more apt to be formed, but the deposition rate is slower than those in the other states. In the metallic mode, the reactive gas is not present within the chamber in an amount sufficient to change the surface of the target in use from a metal into a compound, and the metal is present at a higher ratio than the compound in the target surface. As a result, the deposition rate in the metallic mode is higher than that in the compound mode, but a film formed on the deposition substrate is a metal film. The transition mode is a mode between the compound mode and the metallic mode, and it represents a state where the reactive gas is present within the chamber in such an amount as partly changing the target surface from a metal into a compound. In the transition mode, therefore, the deposition rate is higher than that in the compound mode, and the compound with a composition close to the stoichiometric proportion can be obtained depending on conditions. Thus, the deposition in the transition mode is commonly performed on the industrial basis.

However, because the transition mode provides an instable region in which the deposition rate is changed highly sensitively to a flow rate of the reactive gas, the deposition rate needs to be controlled in order to ensure stable deposition. From that point of view, plasma emission monitoring (hereinafter abbreviated to “PEM”) control is generally often performed to control the deposition rate in a manner of monitoring a plasma emission with the PEM, and adjusting the flow rate of the reactive gas. Japanese Patent Laid-Open No. 2002-180247 proposes a method of, in addition to ordinary PEM control of adjusting the flow rate of the reactive gas to keep plasma emission intensity monitored by the PEM control equal to a setting value, modifying the setting value of the plasma emission intensity on the basis of a cathode discharge voltage.

When the reactive sputtering is applied to an optical film, thickness and absorption of the film needs to be checked to ensure that the film satisfies predetermined performance. In the case of successively forming a compound film on a large number of substrates for a long period, the compound film is formed inside a vacuum chamber as well. The deposition rate for checking the film thickness is controlled in the PEM control. In some of apparatuses, however, a potential distribution inside the vacuum chamber is greatly changed due to change in conductivity of member surfaces inside the vacuum chamber, whereby not only the discharge voltage during the deposition, but also the discharge voltages in the metallic mode and the compound mode are greatly changed. Thus, film quality is changed and film absorption is also changed in some cases.

### SUMMARY OF THE DISCLOSURE

The present disclosure provides a reactive sputtering apparatus to perform deposition in any one of a compound mode, a transition mode, and a metallic mode by employing a target and reactive gas, the reactive sputtering apparatus including a feeding unit arranged to introduce inert gas, a feeding unit arranged to introduce the reactive gas, a power supply unit arranged to supply electric power to the target, a detection unit arranged to detect plasma emission generated upon the electric power being supplied to the target, and a control unit configured to adjust a flow rate of the reactive gas to maintain, at a designated value, plasma emission intensity at a predetermined wavelength or a value calculated from plasma emission intensities at a plurality of predetermined wavelengths, wherein the control unit controls the designated value for the plasma emission intensity or the value calculated from the plasma emission intensities such that a ratio V/V_{c} of a cathode voltage V in the transition mode to a cathode voltage V_{c} in the compound mode comes closer to a preset value, both the cathode voltages being supplied from the power supply unit and detected during the deposition.

The present disclosure further provides a reactive sputtering method to perform deposition in any one of a compound mode, a transition mode, and a metallic mode by employing a target and reactive gas, the reactive sputtering method including a step of introducing inert gas, a step of introducing the reactive gas, and a step of adjusting a flow rate of the reactive gas such that intensity of plasma emission at a predetermined wavelength or a value calculated from intensities of plasma emission at a plurality of predetermined wavelengths, the plasma emission being generated upon supply of electric power to the target, comes closer to a designated value, wherein, in the adjusting step, the designated value for the plasma emission intensity or the value calculated from the plasma emission intensities is controlled during the deposition such that a ratio V/V_{c} of a cathode voltage V in the transition mode to a cathode voltage V_{c} in the compound mode comes closer to a preset value, both the cathode voltages being detected during the deposition when the electric power is supplied.

Further features of the present disclosure will become apparent from the following description of exemplary embodiments with reference to the attached drawings.

### BRIEF DESCRIPTION OF THE DRAWINGS

FIG. 1 is an illustration referenced to explain an embodiment of the present disclosure.

FIG. 2 represents a relation between a flow rate of reactive gas and a cathode voltage in an embodiment of the present disclosure.

FIG. 3 is a flowchart in an embodiment of the present disclosure.

FIG. 4 represents time-dependent change of the cathode voltage in an embodiment of the present disclosure.

FIG. 5 represents a designated value update method in EXAMPLE 1 of the present disclosure.

FIG. 6 represents a designated value update method in EXAMPLE 2 of the present disclosure.

### DESCRIPTION OF THE EMBODIMENTS

Embodiments of the present disclosure provide a method and an apparatus of suppressing change of film quality, which is unintentionally caused due to environmental change inside the apparatus, etc. when deposition is successively performed on a plurality of substrates by a reactive sputtering process while controlling a deposition rate. In a control method of adjusting a flow rate of reactive gas such that plasma emission intensity at a predetermined wavelength or a value calculated from plasma emission intensities at a plurality of predetermined wavelengths during the deposition comes closer to a designated value, the designated value for the plasma emission intensity or the value calculated from the plasma emission intensities is modified using a ratio of a cathode voltage in a transition mode to a cathode voltage in a compound mode during the deposition. As a result, change of the film quality is suppressed.

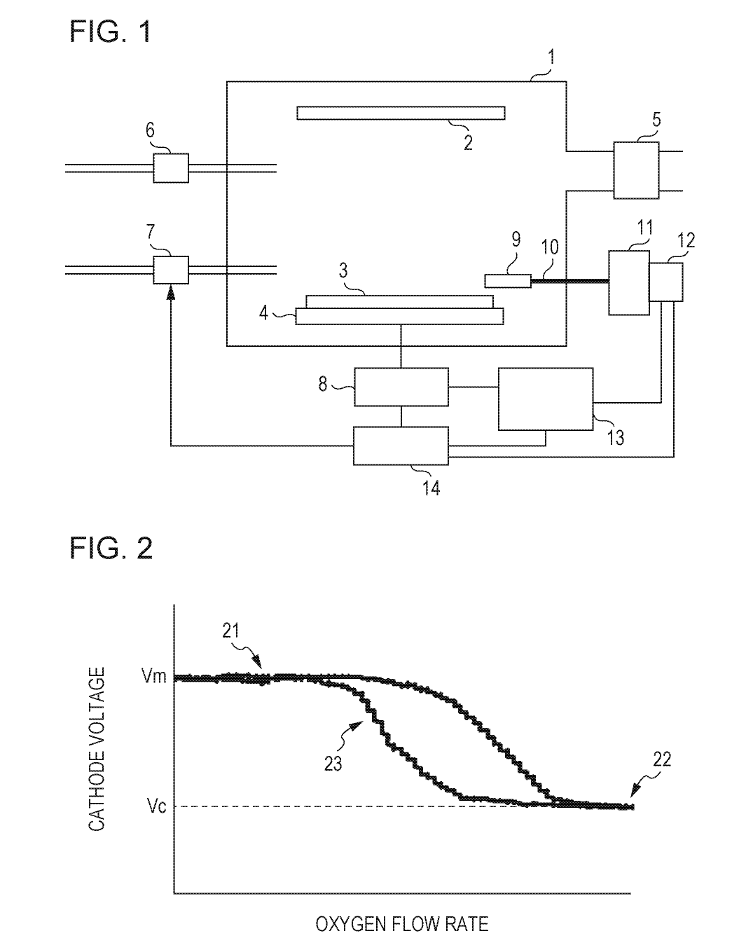

The principle and an embodiment of the present disclosure will be described in detail below with reference to FIGS. 1 to 4. FIG. 1 is a schematic view of a reactive sputtering apparatus according to the embodiment of the present disclosure. A substrate 2, a metal target 3 providing a deposition material, and a cathode 4 electrically connected to the target are arranged inside a vacuum chamber 1. Gases are introduced to the vacuum chamber 1 through a mass flow controller 6 that serves as an inert-gas feeding unit and controls an amount of introduced inert gas, and through a mass flow controller 7 that serves as a reactive-gas feeding unit and controls an amount of introduced reactive gas. Those gases are evacuated by a pump 5.

A gas pressure inside the vacuum chamber 1 is adjusted by controlling the mass flow controllers 6 and 7, and plasma is generated inside the vacuum chamber 1 by supplying electric power to the cathode 4 from a power supply 8, i.e., a power supply unit. With inert gas ions in the plasma impinging against a surface of the target 3, the material of the target 3 is sputtered and reacts with the reactive gas, whereby a compound film is formed on the substrate 2 that is arranged at a position opposing to the target 3.

The reactive sputtering apparatus includes a plasma emission monitoring controller to control a deposition rate and a film thickness during the deposition. The plasma emission monitoring controller includes a collimator 9, an optical fiber 10, a spectroscope 11, a detector 12, a control parameter calculation unit 13, and a control unit 14. The collimator 9 is installed near the target 3 to collect and introduce plasma emission into the optical fiber 10. The plasma emission is introduced to the spectroscope 11 through the optical fiber 10, and is decomposed by the spectroscope 11 into a spectral form. Intensity of the plasma emission per wavelength is detected by the detector 12.

The control unit 14 of the plasma emission monitoring controller adjusts the mass flow controller 7 for the reactive gas by employing the plasma emission intensity at a particular wavelength, which has been detected by the detector 12. A value of the plasma emission intensity at a particular wavelength may be replaced with a value calculated from the plasma emission intensities at a plurality of wavelengths. Such a value is called a PEM control monitored value hereinafter. In this embodiment, the reactive sputtering apparatus includes not only a unit of performing general PEM control, but also the control parameter calculation unit 13 that is a feature of this embodiment.

FIG. 2 represents a relation between a flow rate of the reactive gas and a cathode voltage in the embodiment. As seen from FIG. 2, reactive sputtering exhibits hysteresis characteristics in which the cathode voltage takes different paths between when the flow rate of the reactive gas increases and when the flow rate of the reactive gas decreases. In FIG. 2, a stable state when the flow rate of the reactive gas is relatively large corresponds to a compound mode 22 in which the target surface is covered with a compound, and a stable state when the flow rate of the reactive gas is relatively small corresponds to a metallic mode 21 in which a metal is present at the target surface. An intermediate state between the above two states corresponds to a transition mode 23 in which the deposition rate changes quickly.

The metal of the target material is formed in the metallic mode 21 among the above three modes corresponding to three different regions, and a compound having a stoichiometric proportion is formed in the compound mode 22. In the transition mode 23, a film is formed which has a composition ratio between the metal and the compound, or which is in a mixed state of the metal and the compound.

A compound coverage rate of the target greatly affects supply of electrons to the plasma, and is strongly linked with a plasma impedance. A relation between the compound coverage rate θ of the target surface and the cathode voltage V in the transition mode during the deposition is expressed by the following equation 1 based on an equation that is used as good approximation in above-cited Non-Patent Literature 1. The following equation 2 is obtained by rewriting the equation 1 with respect to θ.

V=Vₘ+θ(V_{c}−Vₘ) Eq. 1

θ=(Vₘ−V)/(Vₘ−V_{c})=(Vₘ/V_{c}−V/V_{c})/(Vₘ/V_{c}−1) Eq. 2

Here, θ denotes the compound coverage rate of the target surface, V denotes the cathode voltage in the transition mode during the deposition, Vₘ denotes the cathode voltage in the metallic mode, and V_{c} denotes the cathode voltage in the compound mode. By controlling the coverage rate θ, a metal ratio in the film formed on the substrate 2 can be controlled, and change in absorption coefficient of the film can be suppressed. A ratio Vₘ/V_{c} of the cathode voltage Vₘ in the metallic mode to the cathode voltage V_{c} in the compound mode can be regarded as corresponding to a ratio in secondary electron emission coefficient between when the inert gas ions impinge against the metal and when the inert gas ions impinge against the compound. Furthermore, it is experimentally found that the ratio Vₘ/V_{c} is very stable in comparison with changes of the other voltages depending on environments inside the vacuum chamber. Thus, by measuring Vₘ/V_{c} in advance, the coverage rate of the target surface during the deposition can be obtained using a ratio V/V_{c} of the cathode voltage V_{c} in the compound mode immediately after start of the deposition to the cathode voltage V in the transition mode during the deposition. In the case of successively performing the deposition on a large number of substrates, the PEM control monitored value is held constant by the PEM control, but film quality may be unintentionally changed when the impedance inside the vacuum chamber 1 is greatly changed due to environmental change inside the vacuum chamber, etc. By holding the coverage rate constant, the state (coverage rate) of the target surface can be held constant even when the voltages inside the apparatus are changed. As a result, a metal amount in a film formed on the substrate can be held constant, and change of the absorption coefficient caused by change of the metal amount can be suppressed.

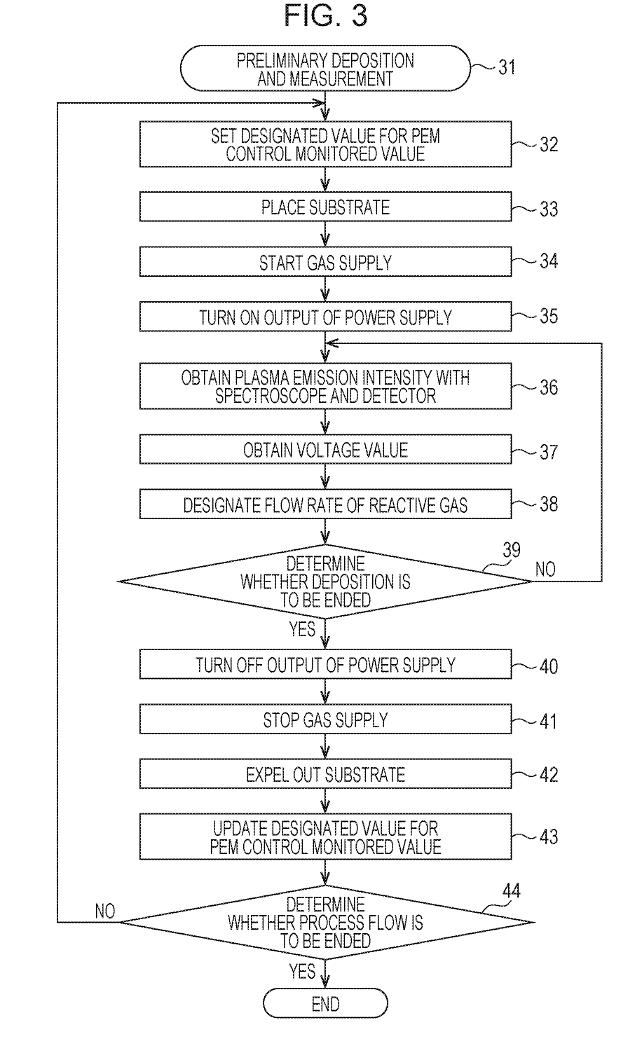

FIG. 3 is a flowchart in the embodiment. In a preliminary measurement step 31, the PEM control monitored value and the voltage values when the flow rate of the reactive gas is changed as illustrated in FIG. 2 are obtained before starting the deposition, thereby checking the cathode voltage Vₘ in the metallic mode and the cathode voltage V_{c} in the compound mode. Furthermore, a plurality of designated values for the PEM control monitored values are determined from the measurement results, and the deposition is performed at each of the designated values. The deposition rate and the absorption coefficient at each of the designated values are obtained from the thickness, the transmittance, and the reflectance of a formed thin film. In a step 32 of setting a designated value for control of the plasma emission intensity, a setting value of the PEM control monitored value is determined from the results of the preliminary measurement step 31 such that the desired deposition rate and absorption coefficient are obtained. In a step 33 of placing the substrate, the substrate is placed. In a step 34 of starting gas supply, the inert gas and the reactive gas are introduced. In a step 35 of turning on the output of the power supply, supply of electric power to the cathode is started. The supplied electric power may be DC, RF or pulse power.

Plasma is generated near the target upon supply of the electric power to the cathode. In a step 36 of obtaining the plasma emission intensity with the spectroscope and the detector, the plasma emission is captured at a designated exposure time and period. The plasma emission is captured through the collimator and the optical fiber, and the plasma emission intensity is obtained at the designated wavelength with the spectroscope 11 and the detector 12. In a step 37 of obtaining a voltage value, the cathode voltage detected in the power supply is obtained at the designated period. In a step 38 of designating the flow rate of the reactive gas, the flow rate of the reactive gas is adjusted with PID control, etc. such that the plasma emission intensity obtained in the step 36 of obtaining the plasma emission intensity is maintained at the value set in the step 32 of setting the designated value for the control. In a step 39 of determining whether the deposition is to be ended, until a deposition time or an integrated value of the PEM control monitored value exceeds a preset value, the process flow is returned to the step 36 of obtaining the plasma emission intensity, and the subsequent steps are repeated. If the determination result as to whether the deposition is to be ended is YES, the supply of the electric power is stopped in a step 40 of turning off the output of the power supply, the gas supply is stopped in a step 41 of stopping the gas supply, and the substrate for which the deposition has finished is expelled out in a step 42 of expelling out the substrate. Thereafter, in a step 43 of updating the designated value for the PEM control monitored value, the designated value for the PEM control monitored value in the next deposition is calculated in the control parameter calculation unit 13 on the basis of the plasma emission intensity obtained in the step 36 and the cathode voltage value obtained in the step 37.

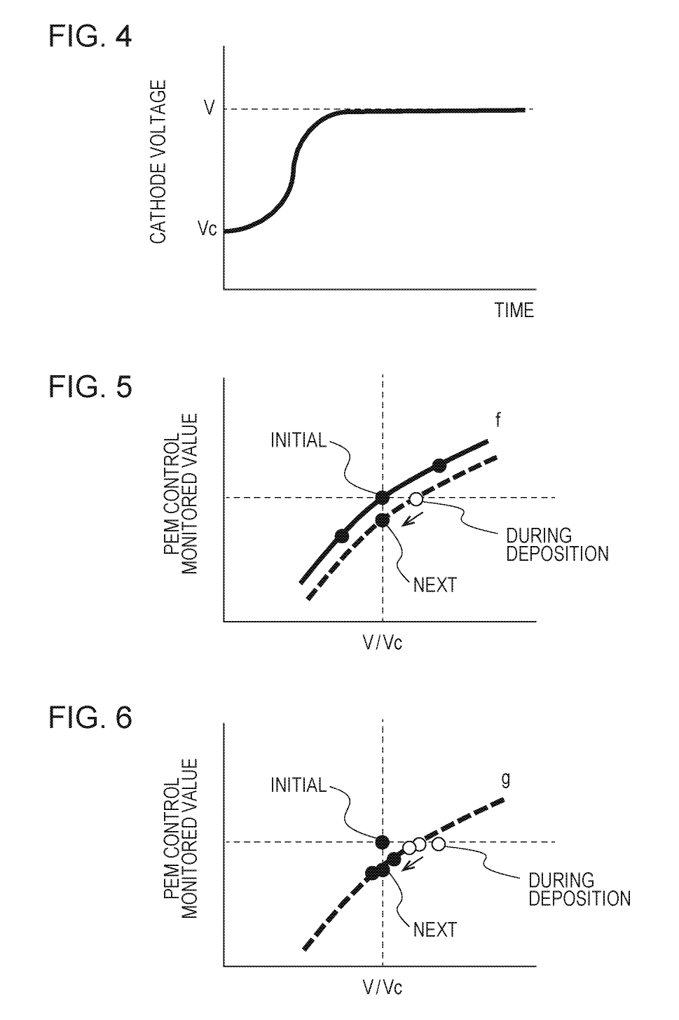

FIG. 4 represents a relation between time and the cathode voltage when the deposition is performed through the steps 34 to 41 in FIG. 3. By supplying electric power after starting the supply of the reactive gas, the cathode voltage starts to rise from the voltage V_{c} in the compound mode and changes to the voltage V in the transition mode as illustrated in FIG. 4. As described above, by holding V/V_{c} constant during the deposition, the metal amount in the film formed on the substrate can be held constant, and change of the absorption coefficient can be suppressed. In the step 43 of updating the designated value for the PEM control monitored value in FIG. 3, the designated value for the PEM control monitored value is calculated such that V/V_{c} takes an initial designated value as illustrated in FIG. 5. If a step 44 of determining whether the process flow is to be ended indicates the presence of the next deposition, the process flow is returned to the step 32, and a value updated in the step 43 is set as the designated value for the PEM control monitored value. The steps 32 to 43 are then repeated. On that occasion, when a determination condition in the step 39 of determining whether the deposition is to be ended is given as time, an end time is also updated corresponding to the step 43 of updating the designated value for the PEM control monitored value.

If the determination result in the step 44 of determining whether the process flow is to be ended is NO, the process flow is returned to the step 32 of setting the designated value for the PEM control monitored value, and the designated value updated in the step 43 is set. Furthermore, the next substrate 2 is placed, and the steps 34 to 43 are executed until the determination result in the step 44 of determining whether the process flow is to be ended becomes YES. Thus, according to this embodiment, in the reactive sputtering, the deposition rate is controlled with the PEM control, and the PEM control is modified in the next and subsequent depositions on the basis of the cathode voltages in the compound mode and the transition mode during the deposition such that a deviation of the film quality, such as change of the film absorption, does not occur. As a result, the desired film thickness can be obtained in stable film quality for a comparatively long period.

FIG. 3 represents the process flow when a single-layer film is successively formed on a plurality of substrates. When a plurality of target materials are arranged inside one vacuum chamber and a multilayer film is formed on a substrate by employing the target materials, the deposition and the measurement are performed for each of the film materials in the step 31 of performing the preliminary deposition and measurement, and the step 32 of setting the designated value for the PEM control monitored value and the step 43 of updating the designated value for the PEM control monitored value are executed for each of the film materials. By updating the designated value for the PEM control monitored value for each of the film materials as described above, the metal amount in each of the films formed on the substrate can be held constant, and unintentional change of the absorption coefficient can be suppressed even when the multilayer film is successively formed on the substrates for a long period.

### EXAMPLE 1

EXAMPLE 1 will be described below with reference to FIG. 1. The reactive sputtering apparatus was constituted as follows.
Volume of Vacuum Chamber: width 450 mm×depth 450 mm×height 500 mm
Evacuation Mechanism: turbo-molecular pump, dry pump
Power Supply: DC pulse power supply
Target Shape: diameter ϕ 8 inches×thickness 5 mm
Target Material: Si
Inert Gas: Ar
Reactive Gas: O₂
Reachable Pressure: 1×10⁻⁵ Pa

A reactive sputtering apparatus according to this EXAMPLE is described. A lens constituting the substrate 2, the Si target 3 providing a deposition material, and the cathode 4 electrically connected to the target 3 are arranged inside the vacuum chamber 1. Ar gas and oxygen gas are introduced to the vacuum chamber 1 through the mass flow controller 6 that controls an amount of the introduced Ar gas, and through the mass flow controller 7 that controls an amount of the introduced oxygen gas. Those gases are evacuated by the pump 5.

The gas pressure inside the vacuum chamber 1 is adjusted by the mass flow controllers 6 and 7, and plasma is generated inside the vacuum chamber 1 by supplying constant electric power of 500 W to the cathode 4 from the power supply 8. A compound film is thus formed on the substrate 2. The deposition rate during the film formation is subjected to the PEM control using the plasma emission monitoring controller. In the plasma emission monitoring controller, the spectroscope 11 disperses light in a wavelength range of 200 nm to 800 nm into a spectrum at a wavelength resolution of 1 nm. The intensity of the dispersed light per wavelength is detected by the CCD detector 12 attached to the spectroscope 11.

A process flow in this EXAMPLE will be described below with reference to FIG. 3. In this EXAMPLE, a process of forming a single-layer film on each lens is successively performed on a plurality of lenses. In this EXAMPLE, a ratio of the plasma emission intensity at the emission wavelength of Si as the target material to the plasma emission intensity at the emission wavelength of Ar is used as the PEM control monitored value. In the preliminary measurement step 31, the PEM control monitored value and the voltage values when an oxygen flow rate is changed as illustrated in FIG. 2 are obtained, before starting the deposition, thereby checking the cathode voltage Vₘ in the metallic mode and the cathode voltage V_{c} in the compound mode. A plurality of designated values for the PEM control monitored values are determined from the measurement results, and the deposition is performed at each of the designated values. The thickness, the transmittance, and the reflectance of a formed thin film are measured using a spectrophotometer, and the deposition rate and the absorption coefficient at each of the designated values are obtained. In the step 32 of setting the designated value for control of the plasma emission intensity, an initial setting value of the PEM control monitored value is determined from the results of the preliminary measurement step 31 such that the desired deposition rate and absorption coefficient are obtained. In the steps 33 to 35, after placing the substrate 2, the Ar gas and the oxygen gas are introduced, and electric power is supplied to the cathode 4. In the step 36 of obtaining the plasma emission intensity with the spectroscope and the detector, the plasma emission is captured at a designated exposure time and period. The plasma emission is dispersed into a spectrum and detected. In the step 37 of obtaining the voltage value, the cathode voltage is obtained at the designated period. In the step 38 of designating the flow rate of the reactive gas, the flow rate of the oxygen gas is adjusted with PID control such that the PEM control monitored value is held at the designated value. The process flow is returned to the step 36 of obtaining the plasma emission intensity, and the subsequent steps are repeated until the integrated value of the PEM control monitored value exceeds the preset value.

If the determination result as to whether the deposition is to be ended is YES, the supply of the electric power is stopped, the gas supply is stopped, and the lens 2 is expelled out in the step 40 to 42, respectively. In the step 43 of updating the designated value for the PEM control monitored value, the designated value for the next deposition is calculated on the basis of the data obtained during the deposition.

A method of updating the designated value for the PEM control monitored value in this EXAMPLE is described. FIG. 5 represents a relation between a PEM control monitored value Ip measured in the preliminary measurement and V/V_{c} at that time. The following equation 3 is obtained as a quadratic approximation f from three-point data:

Iₚ=f(V/V_{c}) Eq. 3

Then, V/V_{c} during the deposition is determined according to FIG. 4. V_{c} is given as a value, at time=0, of an approximation function of the voltage value during a period of several seconds from just after the start of the deposition in FIG. 4. V_{c} is given as an average value in a stationary region where the cathode voltage is settled to a constant value through the PID control. It is assumed that the initial designated values before starting the deposition are Iₚ₀ and V₀/V_{c0}, that a measured value during the deposition on the lens is V/V_{c}, and that a function f representing a relation, denoted by a dotted line in FIG. 5, between the PEM control monitored value and V/V_{c} during the deposition is approximated by a constant multiple of the function f. Thus, V/V_{c} can be held at the previously set value by providing a numerical value Iₚ of the designated value for the PEM control monitored value after the update as expressed by the following equation 4. The numerical value Iₚ after the update is the constant multiple of Iₚ₀.

Iₚ=Iₚ₀²/f(V/V_{c}) Eq. 4

In this EXAMPLE, as described above, the control unit 14 obtains, as the function f of the ratio V/V_{c}, the plasma emission intensity or the value calculated from the plasma emission intensities, which is or are measured before starting the deposition, during the process from the compound mode to the metallic mode through the transition mode. Then, the control unit 14 controls the above-mentioned designated value by employing both the value f(V/V_{c}) of the function f obtained from V/V_{c} during the deposition and the initial designated value for the plasma emission intensity or the value calculated from the plasma emission intensities. More specifically, the control unit 14 determines the approximation function f′, which is the constant multiple of the function f, from V/V_{c} during the deposition and the initial designated value for the plasma emission intensity or the value calculated from the plasma emission intensities, as expressed by the equation 4. Then, the control unit 14 sets, as the designated value after being controlled, the plasma emission intensity or the value calculated from the plasma emission intensities, which is given by the approximation function f′ at the initial ratio V₀/V_{c0}. The foregoing point is represented in FIG. 5.

As seen from the above description, by updating the designated value for the PEM control monitored value for each of the depositions, the state (coverage rate) of the target surface can be held constant and the metal ratio in the formed film can also be held constant even when the deposition is successively performed on a plurality of lenses for a long period. As a result, a rate at which the absorbance at the start of the deposition can be held less than 1% is about 95% during a period until next maintenance of the apparatus is to be made.

### EXAMPLE 2

While the designated value for the PEM control monitored value is updated in EXAMPLE 1 by employing data obtained during the just preceding deposition, the designated value for the PEM control monitored value is updated in EXAMPLE 2 by employing an average value of data obtained from a plurality of latest depositions.

The configuration of the apparatus and the process flow are the same as those in EXAMPLE 1. A method of updating the designated value for the PEM control monitored value according to the feature of this EXAMPLE is described. FIG. 6 represents a relation between an initial PEM control monitored value Ip measured in the preliminary measurement and V/V_{c} at that time. The deposition is repeated three times, and the designated value for the PEM control monitored value is updated by the method used in EXAMPLE 1. In this EXAMPLE 2, per each of the latest plural depositions, the control unit 14 obtains, as the function f of the ratio V/V_{c}, the plasma emission intensity or the value calculated from the plasma emission intensities, which is or are measured before starting each deposition, during the process from the compound mode to the metallic mode through the transition mode. Then, the control unit 14 controls the above-mentioned designated value by employing the value f(V/V_{c}) of the function f obtained from V/V_{c} during each deposition and the initial designated value for the plasma emission intensity or the value calculated from the plasma emission intensities in the relevant deposition. Furthermore, the control unit 14 executes the update as follows by employing the approximation functions f′, which are each obtained from the initial designated value for the plasma emission intensity or the value calculated from the plasma emission intensities and the ratio V/V_{c} in each of the latest plural depositions, and the initial ratios V/V_{c} obtained from the functions f at the initial designated values for the plasma emission intensity or the values calculated from the plasma emission intensities. Thus, the designated value for next time is controlled using the plasma emission intensities or the values calculated from the plasma emission intensities, which are determined from values of the approximation functions at the initial ratios V/V_{c}. In other words, an approximation function g is determined from the data obtained during the three depositions, and the data of V/V_{c} after updating the designated value for the PEM control monitored value. In the next deposition, the designated value for the PEM control monitored value is updated using the approximation function g. More specifically, the above-mentioned designated value is controlled using an average value of the determined plasma emission intensities or of the values calculated from the determined plasma emission intensities. The foregoing point is represented in FIG. 6. FIG. 6 indicates, in an overlapped state, three white circles each corresponding to a white circle denoted by “DURING DEPOSITION” in FIG. 5, and three black circles each corresponding to a black circle denoted by “NEXT” in FIG. 5, those three white and black circles being obtained in the latest three depositions.

According to this EXAMPLE, particularly when a film thickness of one layer is thin, fluctuation per deposition can be moderated in addition to the advantageous effects obtained with EXAMPLE 1. A rate at which the absorbance at the start of the deposition can be held less than 1% is about 97% during a period until next maintenance of the apparatus is to be made.

The present disclosure is not limited to the above-described embodiment and EXAMPLES, and the present disclosure can be variously modified by persons having the ordinary knowledge in the relevant art within the scope of the technical concept of the present disclosure. For instance, while Si is used as the metal target in above EXAMPLES, Nb, Y, Sn, In, Zn, Ti, Th, V, Ta, Mo, W, Cu, Cr, Mn, Fe, Ni, Co, Sm, Pr, Bi and so on can also be used. While O₂ gas is used as the reactive gas in above EXAMPLES, N, O₂, CO₂ and so on can also be used. While Ar gas is used as the inert gas in above EXAMPLES, He, Ne, Kr, Xe, Rn and so on can also be used. Thus, materials of any of the metal target, the reactive gas, and the inert gas are not limited to those ones used in above EXAMPLES.

According to the present disclosure, a desired film can be formed in stable quality for a comparatively long period.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2017-047967 filed Mar. 14, 2017, which is hereby incorporated by reference herein in its entirety.

What is claimed is:

1. A reactive sputtering apparatus to perform deposition in any one of a compound mode, a transition mode, and a metallic mode by employing a target and reactive gas,
the reactive sputtering apparatus comprising a feeding unit arranged to introduce inert gas, a feeding unit arranged to introduce the reactive gas, a power supply unit arranged to supply electric power to the target, a detection unit arranged to detect plasma emission generated upon supply of the electric power to the target, and a control unit configured to adjust a flow rate of the reactive gas to maintain, at a designated value, plasma emission intensity at a predetermined wavelength or a value calculated from plasma emission intensities at a plurality of predetermined wavelengths,
wherein the control unit controls the designated value for the plasma emission intensity or the value calculated from the plasma emission intensities such that a ratio V/V_{c} of a cathode voltage V in the transition mode to a cathode voltage V_{c} in the compound mode comes closer to a preset value, both the cathode voltages being supplied from the power supply unit and detected during the deposition.

2. The reactive sputtering apparatus according to claim 1, wherein the control unit obtains, as a function f of the ratio V/V_{c}, the plasma emission intensity or the value calculated from the plasma emission intensities, which is or are measured before starting the deposition, during a process from the compound mode to the metallic mode through the transition mode, and controls the designated value by employing a value f(V/V_{c}) of the function f obtained from V/V_{c} during the deposition and the initial designated value for the plasma emission intensity or the value calculated from the plasma emission intensities.

3. The reactive sputtering apparatus according to claim 2, wherein the control unit obtains, as the function f of the ratio V/V_{c}, the plasma emission intensity or the value calculated from the plasma emission intensities, which is or are measured before starting the deposition, during the process from the compound mode to the metallic mode through the transition mode, determines an approximation function f′, which is a constant multiple of the function f, from V/V_{c} during the deposition and the initial designated value for the plasma emission intensity or the value calculated from the plasma emission intensities, and sets, as the designated value after being controlled, the plasma emission intensity or the value calculated from the plasma emission intensities, which is given by the approximation function f′ at an initial ratio V/V_{c}.

4. The reactive sputtering apparatus according to claim 1, wherein, in each of latest plural depositions, the control unit obtains, as the function f of the ratio V/V_{c}, the plasma emission intensity or the value calculated from the plasma emission intensities, which is or are measured before starting each deposition, during the process from the compound mode to the metallic mode through the transition mode, and controls the designated value by employing the value f(V/V_{c}) of the function f obtained from V/V_{c} during each deposition and the initial designated value for the plasma emission intensity or the value calculated from the plasma emission intensities in the relevant deposition, and
by employing the approximation functions, which are each obtained from the initial designated value for the plasma emission intensity or the value calculated from the plasma emission intensities and the ratio V/V_{c} in each of the latest plural depositions, and the initial ratios V/V_{c} obtained from the functions f at the initial designated values for the plasma emission intensity or the value calculated from the plasma emission intensities, the control unit controls the designated value on basis of the plasma emission intensities or the values calculated from the plasma emission intensities, which are determined from values of the approximation functions at the initial ratios V/V_{c}.

5. The reactive sputtering apparatus according to claim 4, wherein the designated value is controlled using an average value of the determined plasma emission intensities or of the values calculated from the plasma emission intensities.

6. A reactive sputtering method to perform deposition in any one of a compound mode, a transition mode, and a metallic mode by employing a target and reactive gas,
the reactive sputtering method comprising a step of introducing inert gas, a step of introducing the reactive gas, and a step of adjusting a flow rate of the reactive gas such that intensity of plasma emission at a predetermined wavelength or a value calculated from intensities of plasma emission at a plurality of predetermined wavelengths, the plasma emission being generated upon supply of electric power to the target, comes closer to a designated value,
wherein, in the adjusting step, the designated value for the plasma emission intensity or the value calculated from the plasma emission intensities is controlled during the deposition such that a ratio V/V_{c} of a cathode voltage V in the transition mode to a cathode voltage V_{c} in the compound mode comes closer to a preset value, both the cathode voltages being detected during the deposition when the electric power is supplied.

7. The reactive sputtering method according to claim 6,
wherein, in the adjusting step, the plasma emission intensity or the value calculated from the plasma emission intensities, which is or are measured before starting the deposition, during a process from the compound mode to the metallic mode through the transition mode is obtained as a function f of the ratio V/V_{c}, and the designated value is controlled by employing a value f(V/V_{c}) of the function f obtained from V/V_{c} during the deposition and the initial designated value for the plasma emission intensity or the value calculated from the plasma emission intensities.

8. The reactive sputtering method according to claim 7,
wherein, in the adjusting step, the plasma emission intensity or the value calculated from the plasma emission intensities, which is or are measured before starting the deposition, during the process from the compound mode to the metallic mode through the transition mode is obtained as the function f of the ratio V/V_{c}, an approximation function f′, which is a constant multiple of the function f, is determined from V/V_{c} during the deposition and the initial designated value for the plasma emission intensity or the value calculated from the plasma emission intensities, and the plasma emission intensity or the value calculated from the plasma emission intensities, which is given by the approximation function f′ at an initial ratio V/V_{c}, is set as the designated value after being controlled.

9. The reactive sputtering method according to claim 6,
wherein, in the adjusting step, per each of latest plural depositions, the plasma emission intensity or the value calculated from the plasma emission intensities, which is or are measured before starting each deposition, during the process from the compound mode to the metallic mode through the transition mode is obtained as the function f of the ratio V/V_{c}, and the designated value is controlled by employing the value f(V/V_{c}) of the function f obtained from V/V_{c} during each deposition and the initial designated value for the plasma emission intensity or the value calculated from the plasma emission intensities in the relevant deposition, and
by employing the approximation functions, which are each obtained from the initial designated value for the plasma emission intensity or the value calculated from the plasma emission intensities and the ratio V/V_{c} in each of the latest plural depositions, and the initial ratios V/V_{c} obtained from the functions f at the initial designated values for the plasma emission intensity or the value calculated from the plasma emission intensities, the designated value is controlled on basis of the plasma emission intensities or the values calculated from the plasma emission intensities, which are determined from values of the approximation functions at the initial ratios V/V_{c}.

10. The reactive sputtering method according to claim 9,
wherein the designated value is controlled using an average value of the determined plasma emission intensities or of the values calculated from the determined plasma emission intensities.
